(19) United States
(12) Patent Application Publication
(10) Pub. No.: US 2011/0143035 A1
(43) Pub. Date: Jun. 16, 2011

(54) Thin Film Deposition System and Method for Depositing Thin Film

(76) Inventors: Byoung Ha CHO, Seongnam-si (KR); Jung Hwa Seo, Seongnam-si (KR); Tae Hyung Kim, Gwangju-si (KR); Dong Kyun Seo, Yongin-si (KR); Su Il Jo, Yongin-si (KR)

(21) Appl. No.: 12/961,321

(22) Filed: Dec. 6, 2010

(30) Foreign Application Priority Data
Dec. 16, 2009 (KR) 10-2009-0125563
Mar. 23, 2010 (KR) 10-2010-0025577
Jul. 29, 2010 (KR) 10-2010-0073488

(51) Int. Cl. C23C 16/448; C23C 16/00

(52) U.S. Cl. 427/255.28; 118/726

(57) ABSTRACT

A thin film deposition system and a method for deposit a thin film are disclosed. A thin film deposition system includes a source material feeder configured to feed source material, a source gas feeder comprising a vaporizer connected with the source material feeder to evaporate the source material fed by the source material feeder, a thin film deposition device connected with the source gas feeder to deposit the evaporated source material fed by the source gas feeder on a treatment object, vaporizer exhaustion unit having an end connected with the vaporizer to ventilate an inside of the vaporizer, and a pressure adjuster connected with the exhaustion tube to adjust the pressure of the exhaustion tube to control the velocity of source material fed to the vaporizer.

### CROSS REFERENCE TO RELATED APPLICATION

This application claims the benefit of the Patent Korean Application Nos. 10-2009-0125563(2009.12.16), 10-2010-0025577(2010.03.23), 10-2010-0073488(2010.07.29), which is hereby incorporated by reference as if fully set forth herein.

### BACKGROUND OF THE DISCLOSURE

1. Field of the Disclosure

The present invention relates to a fabricating device of a semiconductor, more particularly, to a device for feeding a source material and a thin film deposition system including the device, and a method for deposing the thin film.

2. Discussion of the Related Art

Semiconductor processes have been divided into minute assembling processes, only to make a thin film thinner, and it is required to control the micro-divided semiconductor processes precisely. Especially, atomic layer deposition (hereinafter, ALD) has been used for a dielectric layer of such a semiconductor device, a transparent conductor of a liquid crystal display device and a protection layer of an electroluminescent thin film display and variations of them, to overcome limitation of chemical vapor deposition (CVD). The atomic layer deposition (ALD) forms a thin film having an atomic-unit thickness.

According to the ALD, reactants are separately injected on a substrate, which is a wafer, and a reaction cycle of chemical-reactant-saturation-adsorption on a substrate surface is repeated a predetermined number of times to form a thin film.

In addition, the ALD uses a self-surface reaction limited mechanism and it includes four processes performed sequentially and repeatedly. Each of the processes will be described as follows.

After a wafer is loaded in a chamber in a first step, source material is fed into the chamber to induce chemical absorption of the source material on a surface of the substrate.

In a purge step, which is a second step, purge gas is injected to eliminate the remaining source material which fails to be chemical-absorbed. In a third step, reactant gas is fed to induce reaction with the chemical-absorbed source material and an atomic layer is deposited.

Hence, in a fourth step, purge gas is re-fed and remaining reactant gas and reaction by-products are exhausted. The above fourth steps may compose a single cycle and this cycle is repeated to deposit a thin film having a desired thickness.

However, the conventional ALD mentioned above has following disadvantages.

According to thin film deposition system using the ALD to form the thin film, the cycle of the source material injection, purge and reactant gas injection and purge processes has to be repeated several times to form the thin film having the desired thickness, commonly. At this time, after the purge step configured to purge an inside of the chamber, gaseous source material has to be fed to the chamber inside continuously to improve work efficiency. For example, if the time taken to purge the chamber inside is 6 seconds, the source material starts to be supplied to a vaporizer before 3 seconds when the purge is completed.

However, an inside of the vaporizer is being purged by a vaporizer exhaustion unit. Because of that, the source material supplied to the vaporizer is exhausted outside via an exhaustion tube in communication with the vaporizer. In other words, although the source material is supplied to the vaporizer, much amount of source material is lost via the exhaustion tube. Also, the time for source material to stay in the vaporizer is relatively short and the source material fails to be evaporated completely only to be pyrolyzed. Because of that, particles are generated and an evaporation rate of the evaporated source material to the supplied source material has to be low disadvantageously.

Furthermore, as a critical dimension of the semiconductor thin film is decreased, overhang is generated in a top layer when depositing the thin film. Here, the overhang is a phenomenon that the top layer is deposited thicker than a bottom layer. As a result, step coverage deterioration and less thickness of the bottom layer of the thin film result in deterioration of electrical properties.

Still further, the pyrolysis generated because of much inflow of liquid source causes over-consumption of source material and incomplete evaporation of source material in the vaporizer may causes the vaporizer to be polluted enough to generate the particles. That is, since the evaporation rate of the evaporated source material to the supplied source material is lowered, the amount of the source material supplied to the thin film deposition device is then decreased and the amount of the wasted source material is increased.

### SUMMARY OF THE DISCLOSURE

Accordingly, the present invention is directed to a thin film deposition system and a method for depositing a thin film.

Additional advantages, objects, and features of the disclosure will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a thin film deposition system includes a source material feeder configured to feed source material; a source gas feeder comprising a vaporizer connected with the source material feeder to evaporate the source material fed by the source material feeder; a thin film deposition device connected with the source gas feeder to deposit the evaporated source material fed by the source gas feeder on a treatment object; a vaporizer exhaustion unit having an end connected with the vaporizer to ventilate an inside of the vaporizer; and a pressure adjuster connected with the vaporizer exhaustion unit to adjust the pressure of the vaporizer exhaustion unit to control the velocity of source material fed to the vaporizer.

The vaporizer may include a body having a predetermined inner space formed therein to evaporate source material, a filter provided in an upper portion of the inner space formed in the body, the filter comprising a plurality of micro-holes formed therein, and a heater mounted in the body to heat the source material fed to the inner space.

The vaporizer exhaustion unit may be connected with the body of the vaporizer to be in communication with a lower portion of the inner space provided in the vaporizer.

The pressure adjuster may include a gas storage configured to store pressure-adjusting gas therein, and a pressure-adjusting tube having an end connected with the vaporizer exhaustion unit and the other end connected with the gas storage.

The pressure-adjusting gas may be inert gas.

The pressure adjuster may be a throttle valve installed in the vaporizer exhaustion unit, in front of an exhaustion pump, to control an opening rate of the vaporizer exhaustion unit to adjust the pressure of the vaporizer exhaustion unit.

In another aspect of the present invention, a thin film deposition system includes a source material feeder configured to feed source material; a vaporizer configured to evaporate the source material fed by the source material feeder; a chamber connected with the vaporizer, the chamber comprising a reaction space configured to deposit the evaporated source material on a treatment object; a first purge gas feeder configured to fed purge gas to a connection tube to eliminate particles existing in the connection tube located between the vaporizer and the chamber; and a vaporizer exhaustion unit connected with the vaporizer to pump the purge gas fed to the connection tube.

The purge gas fed to the connection tube may be pumped by the vaporizer exhaustion unit, after passing the vaporizer.

The thin film deposition system may further include a closable valve installed in the connection tube to prevent the purge gas from being drawn into the chamber.

The thin film deposition system may further include a second purge gas feeder configured to feed purge gas to the chamber to eliminate the source material not deposited on the treatment object.

The first purge gas feeder and the second purge gas feeder may be combined to be a single member.

The vaporizer may include a housing comprising a predetermined evaporation space; a heater installed adjacent to the evaporation space to heat source material; and a filter installed in an upper portion of the evaporation space, the filter comprising a plurality of micro-holes to atomize the source material.

In a further aspect of the present invention, a method for depositing a thin film, using a thin film deposition system comprising a vaporizer to evaporate source material, a thin film deposition device connected with the vaporizer to deposit a thin film on a treatment object and an vaporizer exhaustion unit configured to ventilate an inside of the vaporizer, the method includes ‘A’ step configured to chemical-absorb the source material on the treatment object by feeding the source material evaporated by the vaporizer to the thin film deposition device; ‘B’ step configured to purge the source material not chemical-absorbed on the treatment object; ‘C’ step configured to form a thin film by injecting reactant gas to the treatment object and reacting the source material with the reactant gas; ‘D’ step configured to purge reaction by-products and non-reaction material remaining in the thin film deposition device, Wherein the pressure of the vaporizer exhaustion unit in communication with the vaporizer is increased in ‘D’ step.

In ‘A’ step, a carrier gas feeder may increase a density of carrier gas, to transport gaseous source material inside the vaporizer to a chamber.

In ‘A’ step, a valve located between the chamber and the vaporizer may be open and all of the gaseous source material inside the vaporizer may be fed to the chamber.

The gaseous source material may be fed to the vaporizer only in ‘D’ step.

‘D’ step includes ‘D1’ step configured not to feed the gaseous source material to the vaporizer, and ‘D2’ step configured to feed the gaseous source material to the vaporizer having the carrier gas and to evaporate the gaseous source material fed to the vaporizer.

Particles existing in the vaporizer may be purged in the step configured to purge the by-products and non-reaction material remaining in the thin film deposition device.

Pressure-adjusting gas may be fed to the vaporizer exhaustion unit to increase the pressure of the vaporizer exhaustion unit and the velocity of source material fed to the vaporizer may be decreased, in the step of increasing the pressure of the vaporizer exhaustion unit.

An opening rate of the vaporizer exhaustion unit may be adjusted to increase the pressure of the vaporizer exhaustion unit and the velocity of source material fed to the vaporizer may be decreased, in the step of increasing the pressure of the exhaustion tube.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure.

In the drawings:

FIG. 1 is a diagram schematically illustrating a thin film deposition system according to an exemplary embodiment of the present invention;

FIGS. 2a and 2b are diagrams illustrating ‘A” shown in FIG. 1 in detail;

FIG. 3 is a diagram schematically illustrating a thin film deposition system according to another embodiment of the present invention;

FIG. 4 is a diagram schematically illustrating a thin film deposition system according to a further embodiment of the present invention;

FIG. 5 is a diagram schematically illustrating a structure of an vaporizer shown in FIG. 5;

FIG. 6 is a flow chart illustrating a method for depositing a thin film according to an embodiment of the present invention;

FIG. 7 is a flow chart illustrating a method for operating a vaporizer of the thin film deposition system according to an embodiment of the present invention;

FIGS. 8a and 8b are diagrams illustrating gas feeding to the vaporizer in each process according to the method for depositing the thin film of the above embodiment;

FIG. 9 is a diagram illustrating gas feeding to a chamber in each process according to the method for depositing the thin film;

FIGS. 10a and 10b are diagrams illustrating a thin film formed on a treatment object having a contact hole formed therein and a thin film formed on the treatment object according to the conventional thin film deposition system, and illustrating a treatment object having a contact hole formed therein and a thin film formed on the treatment object, according to the thin film deposition system according to embodiment of the present invention, respectively; and

FIGS. 11a and 11b are diagrams illustrating a thin film deposited according to the first embodiment of the method for depositing the thin film and illustrating a thin film deposited according to the conventional method for depositing a thin film.

### DESCRIPTION OF SPECIFIC EMBODIMENTS

Reference will now be made in detail to the specific embodiments of the present invention, examples of which are illustrated in the accompanying drawings.

Wherever possible, the same reference numbers will be used throughout the drawings to refer to the same or like parts.

In the accompanying drawings, each thickness of plural layers and areas may be enlarged to present the layers and areas clearly and a thickness ratio of a single layer to another layer may not present a real thickness ratio.

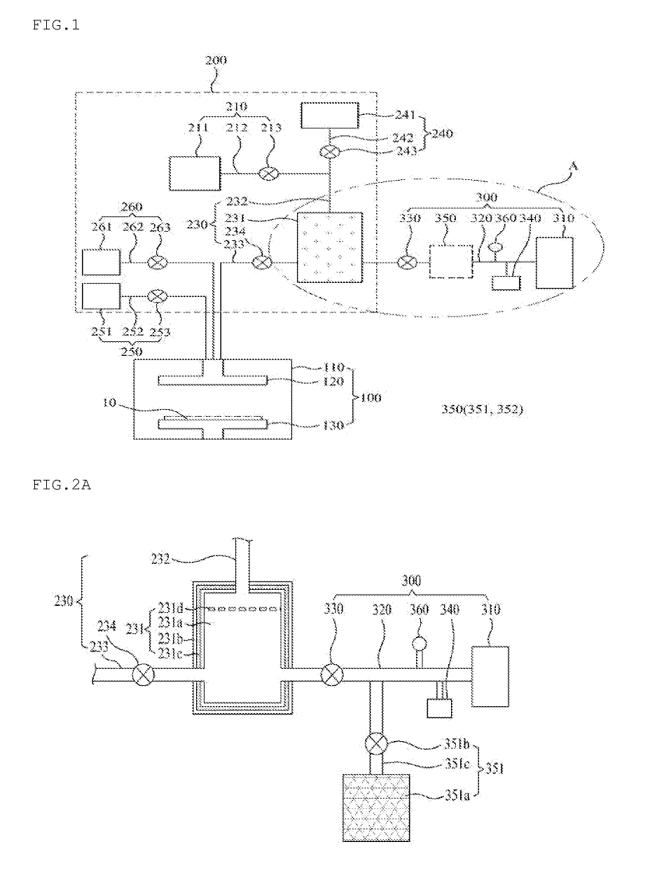

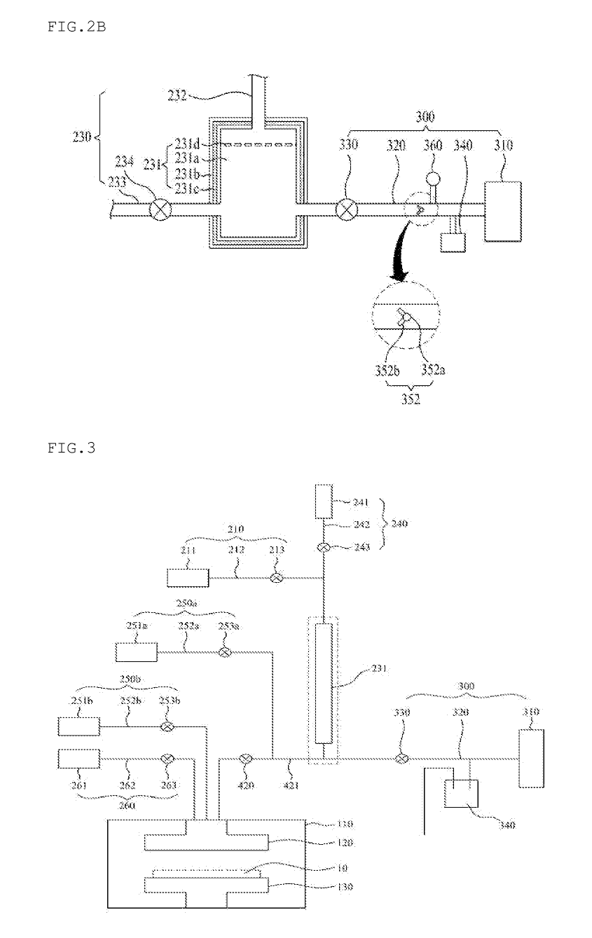

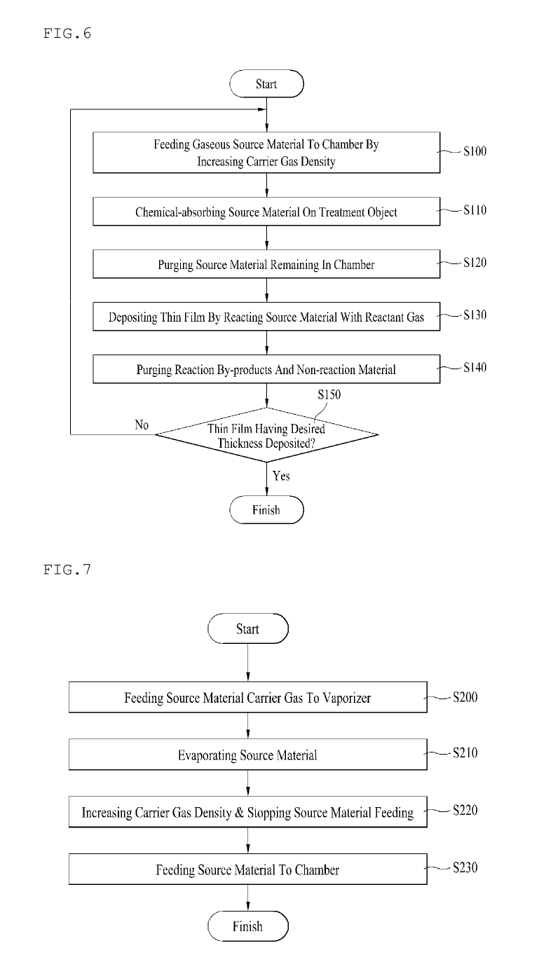

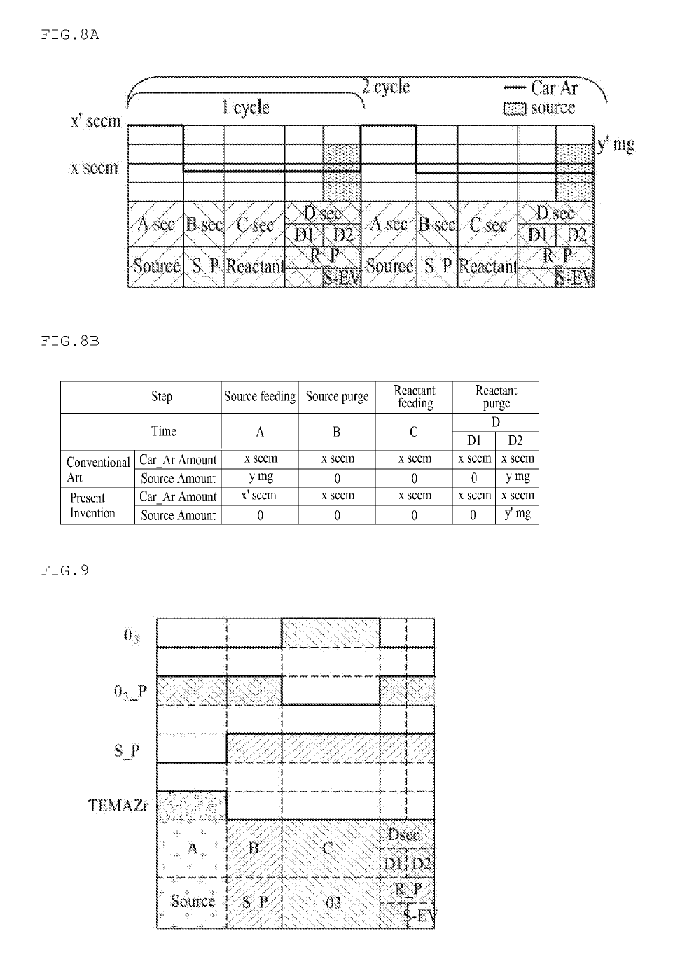

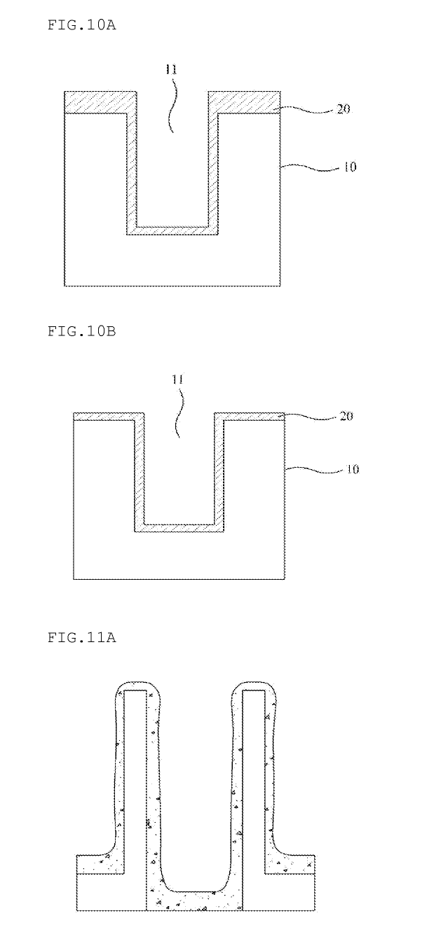

FIG. 1 is a diagram schematically illustrating a thin film deposition system according to an exemplary embodiment of the present invention. FIGS. 2a and 2b are diagrams illustrating ‘A’ shown in FIG. 1 in detail. FIG. 6 is a flow chart illustrating a method for depositing a thin film according to an embodiment of the present invention. FIG. 7 is a flow chart illustrating a method for operating a vaporizer of the thin film deposition system according to an embodiment of the present invention. FIGS. 8a and 8b are diagrams illustrating gas feeding to the vaporizer in each process according to the method for depositing the thin film of the above embodiment. FIG. 9 is a diagram illustrating gas feeding to a chamber in each process according to the method for depositing the thin film. As follows, a source material feeding device and a thin film deposition system including the source material feeding device and a method for depositing a thin film according to an exemplary embodiment will be described in reference to the above drawings.

The thin film deposition system according to this embodiment includes a thin film deposition device 100 having a predetermined reaction space, a source material feeding unit 200 connected with the thin film deposition device 100 to feed gases, which will be used to form a thin film, to the thin film deposition device 100 and a vaporizer exhaustion unit 300 connected with the source material feeding unit 200.

Here, the thin film deposition device 100 includes a chamber 110 having a predetermined reaction space, seating means 130 configured to seat a treatment object 10 thereon and gas injection means 120 arranged in opposite to the seating means 130 to inject source material, reactant gas and purge gas.

Furthermore, a purge gas feeder 250 connected with the gas injection means 120 of the thin film deposition device 100 is provided to feed the purge gas and a reactant gas feeder 260 is provided to feed the reactant gas.

Here, the chamber 110 is fabricated in a hexahedron shape having an empty inside and the chamber according to the present invention may be fabricated in various shapes corresponding to the shape of the treatment object 10, not limited thereto.

The source material feeding unit 200 includes a source material feeder 210 configured to feed liquid source material, a source gas feeder 230 having a vaporizer 231 configured to evaporate the liquid source material fed from the source material feeder 210, and a carrier gas feeder 240 configured to feed carrier gas to move the liquid source material fed from the source material feeder 210 toward the vaporizer 231.

The method for depositing the thin film, using the thin deposition system described above may include ‘A’ step of inducing chemical absorption of source material after loading a wafer in the chamber and feeding the source material in the chamber, ‘B’ step of purging remaining source material failed to be chemical-absorbed by injection purge gas into the chamber, ‘C’ step of depositing an atomic layer by inducing reaction between reactant gas fed into the chamber and the source material chemical-absorbed on a surface of the substrate, and ‘D’ step of purging reaction by-products and no-reaction material by re-feeding the purge gas into the chamber.

In ‘A’ step, a carrier gas feeder increases a density of carrier gas to feed gaseous source material to the chamber. After feeding the gaseous source material to the chamber, the source material is then chemical-absorbed on a treatment object located in the chamber.

First of all, the density of the carrier gas is increased in the vaporizer and the gaseous source material is feed to the chamber (S100).

That is, as shown in FIG. 10a, a contact hole 11 having a large ratio of a length to a breath is formed in the treatment object 10. Here, the ratio of the length to the breath is a ratio of the depth to the width, in other words, the length: the breath. Specifically, if the width is three times as much as the depth, the ratio is high. The high ratio refers to 1:3 of the ratio or more and this embodiment presents the ratio is 1:3 to 1:100. Preferably, the ratio of the length to the breath is 1:5 to 1:20. Here, the contact hole 11 having a high ratio of the length to the breath may be formed in an etching process of the treatment object 10. Of course, the contact hole 11 may be formed through laser irradiation, not limited thereto. The treatment object 10 may be a bear wafer, a wafer having a plurality of patterned thin films, a thin-film-multi-layered material or a die chip, not limited thereto. The treatment object 10 may be multi-layered wafers, multi-layered thin films or multi-layered chips. Alternatively, the treatment object 10 may be multi-layered of at least two of the wafers, thin film multi-layered materials and chips.

Hence, the treatment object 10 having the contact hole 11 is seated on the seating means 130 provided in the chamber 110 of the thin film deposition device 100. Liquid source material is fed to the vaporizer by the source material feeder and the carrier gas feeder 240. According to this embodiment, liquid TEMAZr is used as source material and Ar gas is used as carrier gas.

Once the liquid source material is fed to the inside of the vaporizer 231 by the carrier gas, a heater 231c heats the liquid source material to make it evaporated. When the source material is gaseous in the vaporizer completely, the evaporated source material is supplied to the gas injection means 120 connected with the vaporizer 231 via a source material gas feeding tube 233 connected with the vaporizer 231. After that, the source material injected via the gas injection means 120 is chemical-absorbed on the treatment object 10.

As follows, the vaporizer will be described in detail.

The source material and the carrier gas are fed to the vaporizer (S200). According to this embodiment, liquid TEMAZr is used as source material, the present not limited thereto. A variety of liquid source materials may be used. Preferably, the carrier gas is not reacting with the source material and Argon gas (Ar) is used as carrier gas.

Hence, the source material is evaporated in the vaporizer (S210). The evaporation process of the source material will be described briefly as follows.

First of all, the source material is fed to the inside of the vaporizer by the carrier gas. At this time, the source material passes through a filter and it may be mist, passing micro-holes formed in the filter.

Hence, when the source material is heated by the heater, the liquid source material is evaporated. Here, the mist source material may be evaporated smoothly and easily enough to improve the evaporation rate.

After the density of the carrier gas is increased and the feeding of the source material is stopped (S220), the source material is fed to the chamber (S230). At this time, when the evaporated source material is injected into the chamber by the gas supplying means, the gaseous source material is chemical-absorbed on the treatment object, which is a substrate, located in the chamber (S110).

At this time, in ‘A’ step, a valve located between the camber and the vaporizer is controlled to be open and all of the gaseous source material inside the vaporizer is fed to the inside of the chamber. No source material remains in the vaporizer any more and no source material is fed any more. The operation of the thin film deposition device in the above processes will be described in detail, as follows.

The source material feeder 210 feeds liquid source material to the vaporizer 231 of the gas feeder 230. The source material feeder 210 includes a source material storage 211 configured to store liquid source material therein, a first pipe 212 having an end connected with the source material storage 211 and the other opposite end connected with the source gas feeder 230, and a first valve 213 installed in the first pipe 212 to control communication between the source material storage 211 and the source gas feeder 230. Furthermore, a source material amount adjuster (not shown) may be arranged between the source material storage 211 and the first valve 213, configured to adjust the amount of the source material.

When the source material storage 211 is in communication with the source material gas feeder 230 via the first valve 213 and the first pipe 212, the source material of the source material storage 211 is feeding to the source material gas feeder 230 via the first pipe 212.

The carrier gas feeder 240 includes a carrier gas storage 241 configured to store the carrier gas therein, a second pipe 242 having an end connected with the carrier gas storage 231 and the other opposite end connected with the source material gas feeder 230, and a second valve 243 installed in the second pipe 242 to control communication between the carrier gas storage 241 and the source material gas feeder 230.

When the carrier gas storage 241 is in communication with the source material gas feeder 230 via the second valve 243 and the second pipe 242, the carrier gas of the carrier storage 241 moves to the source material gas feeder 230 via the second pipe 242.

The source material gas feeder 230 is supplied the liquid source material by the source material feeder 210 to evaporate the source material, and then it supplied the evaporated source material to the thin film deposition device 100.

The source material gas feeder 230 includes the vaporizer 231 configured to evaporate the source material, a source material injection tube 232 having a end connected with both the first pipe 212 of the source material feeder 210 and the second pipe 242 of the carrier gas feeder 240 and the other opposite end connected with the vaporizer 231, a source material gas feeding tube 233 having an end connected with the vaporizer 231 and the other opposite end connected with the gas injection means 120 of the thin film deposition device 100, and a third valve 234 installed in the source material gas feeding tube 233 to control communication between vaporizer 231 and the gas injection means 120 of the thin film deposition device 100.

Here, the vaporizer 231 includes a body 231b having a predetermined inner space 231a formed therein to evaporate the liquid source material, a filter 231d arranged in a top portion of the inner space 231a and a heater 231c mounted in the body 231b, surrounding the edge of the inner space 231, to heat and evaporate the liquid source material. As a result, the source material fed from the source material feeder 210 is moved toward the source material injection tube 232 by the carrier gas fed from the carrier gas feeder 240. Once it is injected into the vaporizer 231 via the source material injection tube 232, the source material passes the filter 231d.

Here, the filter 231d is configured to have a plurality of micro-holes formed therein. The source material injected into the body 231b of the vaporizer 231 via the source material injection tube 232 passes the micro-holes of the filter 231d to move below the filter 231d. Because of that, the liquid source material having passed the filter 231d becomes mist.

After that, the vaporizer 231 is in communication with the gas injection means 120 of the thin film deposition device 100 via the third valve 234 and the source material gas feeding tube 233. The source material evaporated in the vaporizer 231 may move toward the gas injection means 120 of the thin film deposition device 100 via the source material gas feeding tube 233.

As mentioned above, when the source material is chemical-absorbed enough on the treatment object in ‘A’ step, with the reaction between the gaseous source material and the treatment object being in saturation, over-fed gaseous source material will not reacts any more.

As a result, in ‘B’ step, the over source material is purged outside the chamber, using purge gas which is an inert gas (S120). In ‘B’ step, the thin film deposition device controls the purge gas feeder to feeds purge gas to the inside of the camber and it purges the gaseous source material which fails to be chemical-absorbed on the treatment object.

The purge gas feeder 250 feeds purge gas to the gas injection means 120 to purge the non-chemical-absorbed source material with respect to the surface of the treatment object 10.

The purge gas feeder 250 includes a purge gas storage 251 configured to store purge gas therein, a third pipe 252 having an end connected with the purge gas storage 251 and the other opposite end connected with the gas injection means 120 of the thin film deposition device 100, and a fourth valve 253 installed in the third pipe 252 to control communication between the purge gas storage 251 and the gas injection means 120. Here, it is obvious that the purge gas is feed to the chamber 110 via the third pipe 252.

Once the over source material is eliminated from the inside of the chamber completely, the feeding of purge gas is stopped and reactant gas is fed to the chamber in ‘C’step (S130). The thin film deposition device controls the reactant gas feeder to spray reactant gas on the treatment object and it enables the gaseous source material to react with the reactant gas, only to form the thin film.

Hence, the reactant gas feeder 260 feeds reactant gas to the gas injection means 120. The reactant gas injected via the gas injection means 120 reacts with the source material chemical-absorbed on the treatment object 10 and the thin film is formed accordingly. According to this embodiment, O2 is used as reactant gas to react with TEMAZr which is the source material to form the thin film formed of ZrO2.

The reactant gas feeder 260 includes a reactant gas storage 261 configured to store reactant gas therein, a fourth pipe 262 having an end connected with the reactant gas storage 261 and the other opposite end connected with the gas injection means 120 of the thin film deposition device 100, and a fifth valve 263 installed in the fourth pipe 262 to control communication between the reactant gas storage 261 and the gas injection means 120. The reactant gas is fed to the chamber 110 from the gas storage 261 via the fourth pipe 262.

Here, the reactant gas reacts with the source material and it enables the thin film deposited on the treatment object. According to this embodiment, TEMAZr is used as source material. If O3 is used as reactant gas, a thin film formed of ZrO3 may be formed on the treatment object. In other words, the source material is chemically combined with the reactant gas and an atomic-layer-unit thin film is then formed on the treatment object (substrate).

In ‘D’ step, purge gas is fed to the inside of the chamber and remaining reaction by-products and reaction non-products are purged (S140) also, in ‘D’ step, source material is fed to the vaporizer for the next process to evaporate the source material, which will be described later.

Here, if the source material is not evaporated in the vaporizer 231 completely, the source material is pyrolyzed only to generate particles. Because of that, particles which might remain in the vaporizer 231 are eliminated by the vaporizer exhaustion unit 300.

The vaporizer exhaustion unit 300 includes an exhaustion pump 310, an exhaustion tube 320 having an end connected with the vaporizer 231 and the other opposite end connected with the exhaustion pump 310, a sixth valve 330 installed in the exhaustion tube 320 to control communication between the vaporizer 231 and the exhaustion pump 310, a trap 340 connected with the exhaustion tube 320 to trap particles generated in the vaporizer 231, a pressure adjuster 350 connected with the exhaustion tube 320 to adjust a pressure inside the exhaustion tube 320, and a pressure measuring device 360 configured to measure the pressure of the exhaustion tube 320.

When the vaporizer 231 is in communication with the exhaustion pump 310 via the sixth valve 330 and the exhaustion tube 320, pumping of the exhaustion pump 310 enables the particles generated in the vaporizer 231 to move toward the trap 340. Because of that, the particles inside both of the vaporizer 231 and the exhaustion tube 320 may be eliminated.

As mentioned above, the process of purging the inside of the vaporizer 231, using the exhaustion unit 300 may be performed in the step of purging the chamber 110 of the thin film deposition device 100. in other words, it is preferable that the inside of the vaporizer 231 is purged by using the exhaustion unit 300 in the purge step which is the last one of the source material injection, purge, reactant gas injection and purge steps, which compose a cycle repeated according to the method for depositing the atomic layer unit thin film.

Here, no source material is fed to the vaporizer in ‘A’, ‘B’ and ‘C’ steps any more. That is, if the liquid source material is fed to the vaporizer too much, the pyrolysis phenomenon would be generated because of the source material which fails to be evaporated completely and the vaporizer would be polluted enough to generate particles. As a result, the gaseous source material is fed to the chamber, using purge gas, after the enough amount of the gaseous source material is stored in the vaporizer. At this time, the feeding of the source material to the vaporizer is stopped.

As shown in FIGS. 8a and 8b, the amount (density) of carrier gas fed to the vaporizer is identical in B, C and D steps. In other words, the amount of carrier gas to be fed to the vaporizer is increased in ‘A’ step, to make smooth the feeding of the gaseous source material to the chamber. The amount of carrier gas is maintained in the other steps.

At this time, ‘D’ step includes ‘D1’ step of not feeding the source material to the vaporizer and ‘D2’ step of feeding source material to the vaporizer having the carrier gas therein and evaporating the source material inside the vaporizer.

That is, as shown in FIG. 8a, only carrier gas is fed to the vaporizer in a first half stage (D1 sec) of ‘D’ step (R_P), with no source material fed to the vaporizer. Source material is fed to the vaporizer together with carrier gas in the second half stage (D2 sec) of ‘D’ step. Here, D1 and D2 may be repeated for the identical time period.

Specifically, in ‘D2’ step, source material may be fed to the vaporizer and a pressure of the exhaustion tube may be increased. At this time, if the pressure of the exhaustion tube is increased, the velocity of the moving source material fed to the vaporizer 231 will be decreased. If the velocity of the moving source material is decreased, the time for the source material to stay in the vaporizer may be increased. As a result, the source material may be evaporated in the vaporizer enough and the evaporation rate of source material may be increased accordingly.

Eventually, the liquid source material fed to the vaporizer may be saved. For example, while y milligram (mg) of source material is fed to the vaporizer in ‘A’ and ‘D2’ steps according to the conventional art, y′ milligram of source material is fed to the vaporizer only in ‘D’ step according to this embodiment.

Here, according to the thin film deposition system, the amount of source material used in ‘A’ and ‘D’ steps is a value which is y (milligram) multiplied by the time (A+D2) (hereinafter, ‘Y milligram’). In contrast, according to this embodiment, the amount may be a value which is y′ (milligram) multiplied by the time (D2) (hereinafter, ‘Y’ milligram) compared with the total source material usage, Y′<Y. when the source material is fed to the vaporizer only in ‘D2’ step, twice times as much as the source material usage may be reduced. Since the source material is fed to the vaporizer only in ‘D2’ step as described above, the effect of source material saving may be improved remarkably.

As a result, the amount of particles generated the pyrolyzed source material without evaporated completely may be reduced. Also, the velocity of the moving source material is decreased and the amount of the source material discharged via the exhaustion tube 320 may be reduced accordingly. Not limited to this, the present invention may adapt a variety of devices as the pressure adjuster 350 to heighten the pressure of the exhaustion tube 320.

In FIG. 2b, a pressure adjusting valve 352 is used as the pressure adjuster 350. Here, the pressure adjusting valve 352 may be in rear of the sixth valve 330 and in front of the exhaustion pump 310, which compose the vaporizer exhaustion unit 300.

The pressure adjusting valve 352 adjusts an opening rate, that is, a hole size of the exhaustion tube 320 to adjust the pressure of the exhaustion tube 320. According to another embodiment, a throttle valve is used as the pressure adjusting valve 352. As shown in FIG. 2b, the throttle valve includes a driving shaft 352a and at least one blade 352b attachedly arranged with respect to the driving shaft 352a.

The blades 352b may be folded or unfolded by way of the driving shaft 352a to adjust the opening rate of the exhaustion tube 320, such that the exhaustion amount of the exhaustion pump 310 may be adjusted. At this time, the pressure adjusting valve 352 may be controlled to allow the pressures of the vaporizer 231 and the exhaustion tube 320 to be 50 torr or more. It is embodied above that the throttle valve is used as the pressure adjusting valve 352 and the present invention is not limited thereto. According to the present invention, any means capable of adjusting the opening rate of the exhaustion tube 320 may be usable.

Here, the pressure adjuster 350 is employed to increase the pressure of the exhaustion tube 320 to decrease the velocity of the moving source material received in the vaporizer 231. The pressure adjuster 350 according to the first embodiment supplies gas for pressure-adjusting to the exhaustion tube 320 to heighten the pressure of the exhaustion tube 320.

Here, the pressure adjuster 350 includes a gas storage 351a configured to store the pressure-adjusting gas therein, a pressure-adjusting tube 351c having an end connected with the gas storage 351a and the other end connected with the exhaustion tube 320, and a seventh valve 351b installed in the pressure-adjusting tube 351c to control communication between the gas storage 31a and the exhaustion tube 320.

When the gas storage 351a is in communication with the exhaustion tube 320 via the seventh valve 351b and the pressure-adjusting tube 351c, the gas stored in the gas storage 351a is supplied to the exhaustion tube 320 via the pressure-adjusting tube 351c.

At this time, the pressure of the exhaustion tube 320 is heightened. According to this embodiment, the pressure of the exhaustion tube 320 is adjusted to be 50 torr or more and N2 gas is used as the pressure-adjusting gas.

The exhaustion tube 320 is installed to communicate with a lower portion of the vaporizer 231. As the pressure of the exhaustion tube 320 is heightened gradually, the velocity of the source material supplied to the vaporizer 231 may be decreased gradually. At this time, the pressure-adjusting gas may be injected to make the pressure of the exhaustion tube 320 reach 50 torr or more. The pressure of the exhaustion tube 320 is measured by using a pressure gage 360 to make the pressure control efficient.

As a result, the source material is evaporated inside the vaporizer enough and the evaporation rate of the source material is then increased.

That is, the pressure of the exhaustion tube 320 is heightened in the last purge step out of the source material chemical-absorption, source material purge, reactant gas injection and purge, which compose the cycle of the atomic layer deposition, for example. Of course, the present invention is not limited thereto. If the time taken by the last purge step is 6 seconds, for example, the source material starts to be fed to the vaporizer 231 before 3 seconds of the purge step completion time and the pressure of the exhaustion tube 320 may be heightened simultaneously. Alternatively, the pressure of the exhaustion tube 320 may be heightened from the former step of the last purge step composing the cycle together with the source material chemical-absorption, source material purge and reactant gas injection. Not limited to the above description, the present invention may allow the pressure of the exhaustion tube 320 to be heightened in each step of the source material chemical-absorption, source material purge, reactant gas injection and purge, which compose the cycle of the atomic layer deposition. When the velocity of the moving source material fed to the vaporizer 231 is decreased because of the heightened pressure of the exhaustion tube 320, the time for the source material to stay in the vaporizer 231 may be increased. Because of that, the source material may be evaporated enough inside the vaporizer 231 and the evaporation rate of the source material may be increased accordingly. As a result, the amount of particles generated by the source material which not evaporated completely but pyrolyzed may be reduced. Since the velocity of the moving source material is decreased, the amount of the source material lost via the exhaustion tube 320 may be decreased.

As the present invention not limited to that, a variety of devices may be useable as the pressure adjuster 350 to heighten the pressure of the exhaustion tube 320.

The steps of A, B, C and D described above may be performed continuously until the thin film having the desired thickness is deposited on the substrate. In other words, the steps of A to D may be repeated if the thin film having the desired thickness is not deposited on the substrate after the reaction by-products and non-reaction material are purged.

At this time, the evaporated source material may be fed to the chamber 10 continuously after the step of purging the reaction by-products and non-reactant gas which remain in the chamber, to improve work efficiency. For example, if the time taken to purge the chamber 110 is 6 seconds, the source material starts to be fed to the vaporizer 231 before 3 seconds from the time of the purge completion. At this time, the pressure of the exhaustion tube 320 is in the state of being heightened by the pressure adjuster 350 as describe above. For example, the pressure adjuster 350 according to the first embodiment supplies the pressure-adjusting gas to the exhaustion tube 320 to adjust the pressure of the exhaustion tube 320 to be 50 torr or more, for example. That is, the pressure-adjusting gas of the gas storage 351a is supplied to the exhaustion tube 320 via the pressure adjusting tube 351b, to adjust the pressure of the exhaustion tube 320 to be 50 torr or more, for example. As the present invention not limited to that, the pressure adjuster 350 according to the second embodiment, that is, the pressure-adjusting valve 353 adjusts opening rate of the exhaustion tube 320 to allow the pressure of the exhaustion tube 320 to be 50 torr or more, for example. Because of that, the lower portion of the vaporizer 231 connected with the exhaustion tube 320 is heightened and the velocity of the source material fed to the vaporizer is reduced then. As a result, the time for the source material to stay in the vaporizer 231 is increased enough to increase the time for which the source material is able to be evaporated. Eventually, the particles generated by the source material not evaporated completely but pyrolyzed may be reduced as much as possible. As the velocity of the source material fed to the vaporizer 231 is decreased, the amount of the source material discharged outside via the exhaustion tube 320 may be decreased.

above is described the method of heightening the pressure of the exhaustion tube 320 provided in the vaporizer exhaustion unit 300 by using the pressure adjuster 350 in the step of purging the inside of the chamber 110 provided in the thin film deposition device 100. However, the present invention is not limited to that and it may be effective to heighten the pressure of the exhaustion tube 320 by using the pressure adjuster in each of the source material injection, purge, reactant gas injection and purge.

Moreover, at a start point of ‘A’ step, there may be an enough amount of evaporated source material inside the vaporizer. Because of that, the liquid source material does not have to be fed to the vaporizer any more in the step of ‘A’.

The density of the carrier gas inside the vaporizer is increased and gaseous source material is re-fed to the chamber (S100). At this time, the operation of the vaporizer is identical to what described above. As shown in FIGS. 5a and 5b, the liquid source material is not fed to the vaporizer in ‘A’ step (A sec) and the gaseous source material evaporated by increasing the amount of carrier gas is fed to the chamber.

As a result, the evaporated source material is injected into the chamber via the gas feeding means and the gaseous source material is re-chemical-absorbed on the treatment object (substrate) located in the chamber (S110).

As mentioned above, the cycle configured of the source material chemical-absorption, purge, thin film deposition and purge steps is repeated. Once the thin film having the desired thickness is deposited on the substrate in repeating the cycle, the process is completed (S150).

According to FIG. 8b, the amount of the source material and carrier gas fed to the vaporizer according to the conventional method is compared with the amount of the source material and carrier gas fed to the vaporizer according to this embodiment. As shown in FIG. 8b, the source material is fed to the vaporizer only in ‘D’ step and the amount of the source material fed to the vaporizer is increased in ‘A’ step according to the method of the present invention.

FIG. 9 is a diagram illustrating the amount of gas fed to the chamber. According to this embodiment, the chemical-absorption of source material described above is repeated for A sec (seconds) and the purge is repeated for B sec and the thin film deposition is repeated for C sec and the purge is repeated for D sec. the second purge is divided into two steps and the two steps of the second purge are performed for D1 sec and D2 sec, and the four steps may be corresponding to the steps of A, B, C and D, respectively.

In other words, in ‘A’ step, auxiliary feeding of source material to the vaporizer having gaseous source material therein may be stopped and the density of carrier gas which is TEMAZr may be increased, to feed the gaseous source material to the chamber. At this time, all of the source material provided in the vaporizer when ‘A’ step starts is fed to the chamber when ‘A’ step is completed.

In ‘B’ step, first purge gas (S_P) is fed to the chamber. Here, the first purge gas is fed to the chamber also in ‘C’ and ‘D’ steps, with the same density as in ‘A’ step.

In ‘C’ step, reactant gas (O3) is fed to the chamber to react with the gaseous source material.

Hence, in ‘D’ step, second purge gas (O3_P) is fed to the chamber. At this time, the second purge gas is fed to the chamber also in ‘A’ and ‘B’ steps, with the same density as in ‘D’ step. as a result, the gaseous source material provided only in the vaporizer is fed to the chamber in a first half stage of the source material feeding step described above and the source material stays only in the chamber in a second half stage of the step.

As shown in FIG. 3, a thin film deposition system according to a second embodiment of the present invention includes a chamber 110, a source material feeder 210, a carrier gas feeder 240, a vaporizer 231, a vaporizer exhaustion unit 300, a reactant gas feeder 260, a first purge gas feeder 250a and a second purge gas feeder 250b.

The chamber 110 forms a predetermined reaction space, in which evaporated source material is deposited, on treatment object 10. In the chamber 110 there are provided seating means 130 configured to seat the treatment object 10 thereon and gas injection means 120 arranged in opposite to the seating means 130 to inject source material, reactant gas and purge gas.

The source material feeder 210 feeds liquid source material to the vaporizer 231. the source material feeder 210 includes a source material storage 211 configured to store the liquid source material therein, a first pipe 212 having an end connected with the source material storage 211 and the other end connected with the vaporizer 231, and a first valve 213 installed in the first pipe 212 to control the amount of source material fed to the vaporizer 231. Liquid TEMAZr is used as source material, for example.

The carrier gas feeder 240 feeds carrier gas used to transport the liquid source material to the vaporizer 231. the carrier gas feeder 240 includes a carrier gas storage 241 configured to store carrier gas therein, a second pipe 242 having an end connected with the carrier gas storage 241 and the other end connected with the vaporizer 231, and a second valve 243 installed in the second pipe to control the amount of carrier gas feed to the vaporizer 231. Here, Ar is used as carrier gas, for example.

The vaporizer 231 evaporates the liquid source material transported by the carrier gas to feed the evaporated source material to the chamber 110. The source material fed to the vaporizer 231 together with the carrier gas is heated by heating means such as a heater to be evaporated and the evaporated source material is then moved into the chamber 110.

The evaporated source material drawn into the chamber 110 is chemical-absorbed on a surface of the treatment object 10 located on the seating means 130. After that, the source material which failed to be chemical-absorbed on the surface of the treatment object 10 may be exhausted by purge gas.

The second purge gas feeder 250b feeds purge gas to the gas injection means 120 to exhaust the gaseous source material not chemical-absorbed on the treatment object 10 outside. the second purge gas feeder 240b includes a purge gas storage 251b configured to store purge gas therein, a third pipe having an end connected with the purge gas storage 251b and the other end connected with the chamber 110, and a third valve 253b installed in the third pipe 252b to control the amount of purge gas feed to the gas injection means 120. Here, Ar is used as purge gas, for example.

After the gaseous source material inside the chamber 110 is exhausted by the purge gas, reactant gas is fed to induce reaction with the source material chemical-absorbed on the surface of the treatment object 10.

The reactant gas feeder 260 injects reactant gas into the chamber 110 to induce the reaction between the gaseous source material and the reactant gas. The reactant gas feeder 260 includes a reactant gas storage 261 configured to store reactant gas therein, a fifth pipe 262 having an end connected with the reactant gas storage 261 and the other end connected with the chamber 110, and a fifth valve 263 installed in the fifth pipe 262 to control the amount of reactant gas. According to this embodiment, O2 is used as reactant gas to react with the source material of TEMAZr to form a thin film of ZrO2.

After a thin film is formed on the surface of the treatment object 10 by feeding reactant gas to the chamber 110, purge gas is re-fed to the chamber 110 and reaction by-products and non-reaction materials are purged.

In ‘A’ step, if the liquid source material fed to the vaporizer 231 is not evaporated completely, such the source material is pyrolyzed only to generate particles. Here, such particles include the liquid source material not evaporated, which will be particles potentially. The vaporizer exhaustion unit 300 is used to eliminate such the particles remaining in the vaporizer 231.

The vaporizer exhaustion unit 300 is employed to pump and eliminate particles existing in the vaporizer 231. the vaporizer exhaustion unit 300 includes an exhaustion pump 310, an exhaustion tube 320 having an end connected with the vaporizer 231 and the other end connected with the exhaustion pump 310, an exhaustion valve 330 installed in the exhaustion tube 320 to control communication between the vaporizer 231 and the exhaustion pump 310, and a trap 340 configured to trap pumped particles. The pumping of the vaporizer exhaustion unit 300 may be performed during the purge step ('B and ‘D’ steps). Preferably, the pumping is performed during ‘D’ step.

In the meanwhile, gaseous source material is supplied to a connection tube 421 connecting the vaporizer 231 with the chamber 110. Even in such the connection tube 421 would be not-evaporated-source material or pyrolyzed particles. If such particles exist in the connection tube 421, various assembling work problems might occur.

Because of that, a step of eliminating particles existing in the connection tube 421 ('E′ step) may be further provided in this embodiment. Such ‘E’ step is performed by the first purge gas feeder 250a.

The first purge gas feeder 250a feeds purge gas to the connection tube 421 to eliminate particles existing in the connection tube 421. the first purge gas feeder 250a includes a first purge gas storage 251a configured to store purge gas therein, a fourth pipe 252a having an end connected with the purge gas storage 251a and the other end connected with the vaporizer 231, and a fourth valve 253a installed in the fourth pipe 252a to control the amount of purge gas fed to the connection tube 421. Here, Ar is used as purge gas, for example.

A closable valve 420 may be installed in the connection tube 421 and the closable valve 420 is employed to closable the purge gas fed to the first purge gas feeder 250a from being drawn into the chamber 110.

The purge gas fed to the connection tube 421 by the first purge gas feeder 250a may be pumped and exhausted by the vaporizer exhaustion unit 300. At this time, the purge gas may eliminate particles existing in the vaporizer 231 also, passing the vaporizer 231 after the connection tube 421.

If the purge gas is fed to the connection tube 421 by the first purge gas feeder 250a, the closable valve 420 is closed to prevent the purge gas from coming into the chamber 110. After that, the purge gas passes the vaporizer 231, together with the particles existing in the connection tube 421. The purge gas pulls the particles existing in the vaporizer 231 to enter the trap 340, using the pumping pressure generated by the exhaustion pump 310.

When the purge gas is fed by the first purge gas feeder 250a, Ar as purge gas may be fed to the vaporizer 231 from the carrier gas feeder 240. The purge gas fed to the vaporizer 231 pulls particles inside the vaporizer 231, to be pumped and exhausted by the vaporizer exhaustion unit 300 together with the purge gas fed to the connection tube 421.

‘E’ step of feeding the purge gas to the connection tube 421 may be performed together with the pumping of the vaporizer exhaustion unit 300. In contrast, ‘E’ step may be performed in a replacing time of the treatment object (for example, wafer) or in another proper time.

As described above, according to this embodiment, the purge gas is fed to the connection tube 421 by the first purge gas feeder 250a and the particles inside both the connection tube 421 and the vaporizer 231 are eliminated. Because of that, assembly work problems which might be generated by particles existing in the deposition device may be prevented. In addition, the purge gas passes the vaporizer 231 and the particles inside the vaporizer 231 also may be eliminated more efficiently. As a result, the replacement interval of the vaporizer 231 may be reduced and the time and expense cost to replace the old vaporizer with a new one may be reduced accordingly.

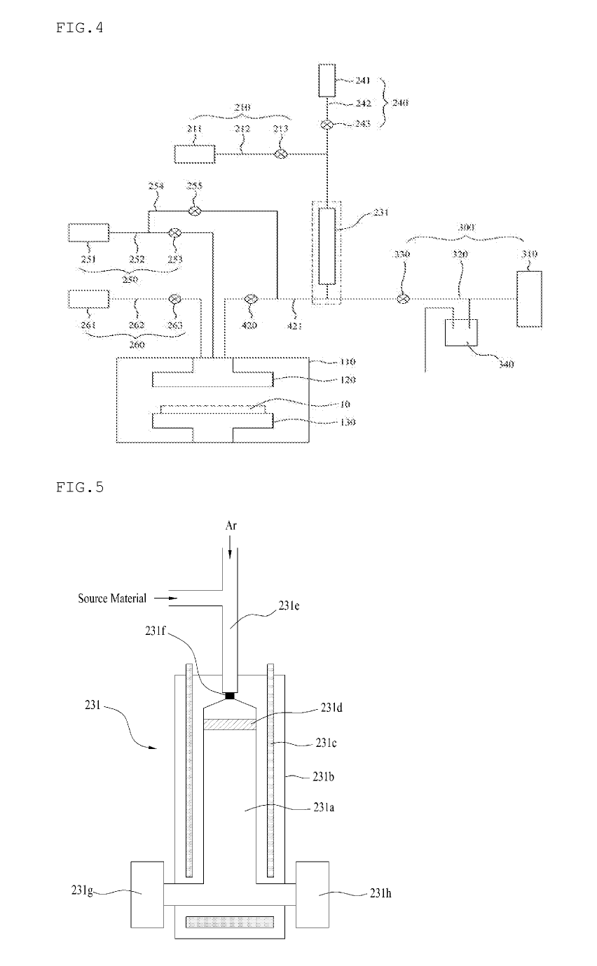

As follows, a thin film deposition system according to a third embodiment will be described in reference to FIG. 4.

This embodiment shown in FIG. 4 has the identical configuration to the above embodiment shown in FIG. 2, except that the first and second purge gas feeders 250a and 250b of FIG. 2 are integrally formed as single member.

According to this embodiment, a purge gas feeder 460 feeds purge gas to gas injection means 120 provided in a chamber 110 and it feeds purge gas to a connection tube 421 simultaneously.

The purge gas feeder 460 includes a purge gas storage 461 configured to store purge gas therein, a third pipe 462 having an end connected with the purge gas storage 461 and the other end connected with the chamber 110, a third valve 463 installed in the third pipe 462 to control the amount of purge gas fed to the gas injection means 120, a fourth pipe having an end connected with the purge gas storage 461 and the other end connected with the vaporizer 231, and a fourth valve 255 installed in the fourth pipe 254 to control the amount of purge gas fed to the connection tube 421. Here, Ar is used as purge gas, for example.

When the purge gas feeder 460 feeds purge gas to the chamber 110, the fourth valve 255 is closed and the third valve 463 is opened. When the purge gas feeder 460 feeds purge gas to the connection tube 421, the third valve 463 is closed and the fourth valve 255 is opened.

According to this embodiment, the first purge gas feeder 250a and the second purge gas feeder 250b shown in FIG. 2 are combined to be a single purge gas feeder 460. Because of that, the thin film deposition device according to this embodiment may have a simpler configuration, with achieving the same effect of the deposition device shown in FIG. 2.

As follows, the configuration of the vaporizer provided in the deposition device according to the present invention will be described in reference to FIG. 5. FIG. 5 is a diagram illustrating the configuration of the vaporizer shown in FIGS. 3 and 4.

The vaporizer 231 includes a housing 231b, an injection hole 231e located in a top of the housing 231b to inject liquid source material and carrier gas, for example, Ar, an evaporation space 231a configured to evaporate the liquid source material therein, a heater 231c installed adjacent to the evaporation space 231a to heat the liquid source material, a chamber connection part 231g connected with the connection tube 421 to feed evaporated source material to the chamber 110, and a pumping line connection part 231h connected with the vaporizer exhaustion unit 300 to exhaust the source material or carrier gas.

An orifice 231f is installed between the injection hole 231e and the evaporation space 231a. When it is fed to the injection hole 231e of the vaporizer 231, the liquid source material has a pressure decreased and a velocity increased, while passing the orifice 231f, and the liquid is expanded.

A filter 231d is installed in an upper portion of the evaporation space 231a and a plurality of micro-holes are formed in the filter 231d. Because of that, liquid source material drawn via the injection hole 231e is atomized, passing the filter 231d, to be evaporated initially. According to this embodiment, the length of the evaporation space 231a is 15 mm and a diameter of each micro-hole installed in the filter 231d is 0.23 mm.

The source material atomized while passing the filter 231d is heated to be evaporated secondarily. The heater 231c may surround the evaporation space 231a entirely.

The temperature and pressure of the evaporation space 231a may affect the evaporation rate of source material seriously. According to this embodiment, the temperature of the evaporation space 231a is maintained between 110° C. and 140° C. and the pressure of the evaporation space 231a is maintained between 80 torr and 120 torr, such that the velocity of the source material fed to the vaporizer 231 may be controlled optimally.

Since the filter 231d is installed in the upper portion of the evaporation space 231a in the vaporizer 231, the liquid source material is initial-evaporated while passing the filter 231d and the source material having passed the filter is secondary-evaporated after heated by the heater 231c. As a result, the evaporation rate of the liquid source material may be improved. FIGS. 10a and 10b are diagrams illustrating the treatment object having the contact hole formed therein and the thin film formed on the treatment object according to the conventional thin film deposition system and illustrating the treatment object having the contact hole formed therein and the thin film formed on the treatment object according to the thin film deposition system according to the present invention, respectively.

In reference to FIG. 10a, the thickness of the thin film formed on the upper surface of the treatment object having the contact hole formed therein according to the conventional thin film deposition system is 17 nm and the thickness of the thin film formed on the lower top surface of the treatment object is 9 nm. As a result, step coverage (S/C) is 60%. In contrast, the thickness of the thin film formed on the upper surface of the treatment object having the contact hole formed therein according to the embodiments of the present invention is 11 nm and the thickness of the thin film formed on the lower top surface of the treatment object is 10 nm. As a result, step coverage (S/C) is 90%. In other words, the step coverage (S/C) of the thin film formed according to the embodiments of the present invention may be 30% higher than the step coverage (S/C) of the thin film formed according to the conventional thin film deposition system. This is because the evaporation rate of source material is improved by increasing the pressure of the exhaustion tube 320 and reducing the velocity of source material fed to the vaporizer 231. In other words, the enough amount of evaporated source material is fed to the thin film deposition device 100 and the thin film having the thickness as large as the thickness of the thin film formed on the upper top surface of the treatment object may be deposited on the bottom of the contact hole accordingly.

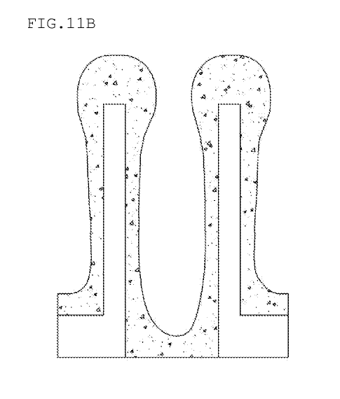

FIGS. 11a and 11b are diagrams illustrating the thin film deposited based on a method of depositing a thin film according to en embodiment and illustrating the thin film deposited based on the conventional method, respectively.

As shown in FIG. 11b, the thin film deposited on the treatment object based on the conventional method is thicker than the thin film deposited on the bottom surface of the contact hole, that is, the lower top surface of the treatment object. However, as shown in FIG. 11b, the thin film deposited on the treatment object based on the method according to the embodiment of the present invention is thinner than the conventional thin film and there is little thickness difference between the thin film formed on the upper top surface and the lower top surface, that is, the bottom of the contact hole.

In other words, the evaporation rate of source material inside the vaporizer is improved and there are no the pyrolysis generated by the source material not evaporated in the vaporizer completely and the particles generated by pollution of the vaporizer generated by the particles.

Furthermore, the time for the source material to stay in the vaporizer may be increased and the amount of source material lost and wasted via the exhaustion tube may be reduced accordingly. As a result, the source material usage may be reduced and the cost of the assembly work process may be reduced.

Still further, the overhang is not generated in the thin film formed on the treatment object. As a result, the step coverage of the semiconductor thin film and the deterioration of electrical properties may not be generated.

The method for depositing the thin film described above may be usable in a fabricating process of a flat panel display device, solar battery and the like, rather than the fabrication process of the thin film deposition on the semiconductor device.

The characteristics, structure, effects of the embodiments may be included in at least one of the embodiment of the present invention, not limited to a specific single embodiment. The characteristics, structures and effects of the embodiments may be combined or modified by those skilled in the art to which the embodiments pertain. As a result, contents relating to such combinations and modifications may be included in a scope of the present invention.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A thin film deposition system comprising:
a source material feeder configured to feed source material;
a source gas feeder comprising a vaporizer connected with the source material feeder to evaporate the source material fed by the source material feeder;
a thin film deposition device connected with the source gas feeder to deposit the evaporated source material fed by the source gas feeder on a treatment object;
a vaporizer exhaustion unit having an end connected with the vaporizer to ventilate an inside of the vaporizer; and
a pressure adjuster connected with the vaporizer exhaustion unit to adjust the pressure of the vaporizer exhaustion unit to control the velocity of source material fed to the vaporizer.

2. The thin film deposition system of claim 1, wherein the vaporizer comprises,
a body having a predetermined inner space formed therein to evaporate source material,
a filter provided in an upper portion of the inner space formed in the body, the filter comprising a plurality of micro-holes formed therein, and
a heater mounted in the body to heat the source material fed to the inner space.

3. The thin film deposition system of claim 1, wherein the vaporizer exhaustion unit is connected with the body of the vaporizer to be in communication with a lower portion of the inner space provided in the vaporizer.

4. The thin film deposition system of claim 1, wherein the pressure adjuster comprises,
a gas storage configured to store pressure-adjusting gas therein, and
a pressure-adjusting tube having an end connected with the vaporizer exhaustion unit and the other end connected with the gas storage.

5. The thin film deposition system of claim 4, wherein the pressure-adjusting gas is inert gas.

6. The thin film deposition system of claim 1, wherein the pressure adjuster is a throttle valve installed in the vaporizer exhaustion unit, in front of an exhaustion pump, to control an opening rate of the vaporizer exhaustion unit to adjust the pressure of the e vaporizer exhaustion unit.

7. A thin film deposition system comprising:
a source material feeder configured to feed source material;
a vaporizer configured to evaporate the source material fed by the source material feeder;
a chamber connected with the vaporizer, the chamber comprising a reaction space configured to deposit the evaporated source material on a treatment object;
a first purge gas feeder configured to fed purge gas to a connection tube to eliminate particles existing in the connection tube located between the vaporizer and the chamber; and
an vaporizer exhaustion unit connected with the vaporizer to pump the purge gas fed to the connection tube.

8. The thin film deposition system of claim 7, wherein the purge gas fed to the connection tube is pumped by the vaporizer exhaustion unit, after passing the vaporizer.

9. The thin film deposition system of claim 4 or 8, further comprising:
a closable valve installed in the connection tube to prevent the purge gas from being drawn into the chamber.

10. The thin film deposition system of claim 7 or 8, further comprising:
a second purge gas feeder configured to feed purge gas to the chamber to eliminate the source material not deposited on the treatment object.

11. The thin film deposition system of claim 10, wherein the first purge gas feeder and the second purge gas feeder are combined to be a single member.

12. The thin film deposition system of claim 7 or 8, wherein the vaporizer comprises,
a housing comprising a predetermined evaporation space;
a heater installed adjacent to the evaporation space to heat source material; and
a filter installed in an upper portion of the evaporation space, the filter comprising a plurality of micro-holes to atomize the source material.

13. A method for depositing a thin film, using a thin film deposition system comprising a vaporizer to evaporate source material, a thin film deposition device connected with the vaporizer to deposit a thin film on a treatment object and an vaporizer exhaustion unit configured to ventilate an inside of the vaporizer, the method comprising
A step configured to chemical-absorb the source material on the treatment object by feeding the source material evaporated by the vaporizer to the thin film deposition device;
B step configured to purge the source material not chemical-absorbed on the treatment object;
C step configured to form a thin film by injecting reactant gas to the treatment object and reacting the source material with the reactant gas;
D step configured to purge reaction by-products and non-reaction material remaining in the thin film deposition device,
wherein the pressure of the vaporizer exhaustion unit in communication with the vaporizer is increased in the D step.

14. The method for depositing the thin film of claim 13, wherein in the A step, a carrier gas feeder increases a density of carrier gas, to transport gaseous source material inside the vaporizer to a chamber.

15. The method for depositing the thin film of claim 14, wherein in the A step, a valve located between the chamber and the vaporizer is open and all of the gaseous source material inside the vaporizer is fed to the chamber.

16. The method for depositing the thin film of claim 14, wherein the gaseous source material is fed to the vaporizer only in the D step.

17. The method for depositing the thin film of claim 14, wherein the D step comprises,
D1 step configured not to feed the gaseous source material to the vaporizer, and
D2 step configured to feed the gaseous source material to the vaporizer having the carrier gas and to evaporate the gaseous source material fed to the vaporizer.

18. The method for depositing the thin film of claim 13, wherein particles existing in the vaporizer are purged in the step configured to purge the by-products and non-reaction material remaining in the thin film deposition device.

19. The method for depositing the thin film of claim 13, wherein pressure-adjusting gas is fed to the vaporizer exhaustion unit to increase the pressure of the vaporizer exhaustion unit and the velocity of source material fed to the vaporizer is decreased, in the step of increasing the pressure of the vaporizer exhaustion unit.

20. The method for depositing the thin film of claim 13, wherein an opening rate of the vaporizer exhaustion unit is adjusted to increase the pressure of the vaporizer exhaustion unit and the velocity of source material fed to the vaporizer is decreased, in the step of increasing the pressure of the vaporizer exhaustion unit.
